(19) United States
(12) Patent Application Publication
(10) Pub. No.: US 2016/0197090 A1
(43) Pub. Date: Jul. 7, 2016

(54) METHOD FOR MANUFACTURING SEMICONDUCTOR DEVICE

(71) Applicant: KABUSHIKI KAISHA TOSHIBA, Tokyo (JP)

(72) Inventor: Toshiyuki SASAKI, Yokkaichi (JP)

(21) Appl. No.: 14/727,065

(22) Filed: Jun. 1, 2015

Related U.S. Application Data
(60) Provisional application No. 62/100,287, filed on Jan. 6, 2015.

(51) Int. Cl. H01L 27/115; H01L 21/311; H01L 21/033

(52) U.S. Cl. CPC H01L 27/11568; H01L 27/11582; H01L 21/0332; H01L 21/31116; H01L 21/0337; H01L 21/31144

(57) ABSTRACT

According to one embodiment, a method for manufacturing a semiconductor device includes forming a stacked mask on a layer to be processed. The stacked mask has a plurality of intermediate films and a plurality of mask films alternately stacked. The method includes forming a stair-shaped portion in a top-layer first intermediate film. The forming the stair-shaped portion includes sliming a top-layer mask film, and etching the first intermediate film exposed by the slimming of the top-layer mask film. The method includes forming a first stair-shaped portion in a second intermediate film by transferring the stair-shaped portion of an upper intermediate film. The method includes forming a second stair-shaped portion following the first stair-shaped portion in the second intermediate film. The forming the second stair-shaped portion includes slimming a mask film immediately above the second intermediate film, and etching the second intermediate film.

### CROSS-REFERENCE TO RELATED APPLICATION

This application is based upon and claims the benefit of priority from U.S. Provisional Patent Application 62/100,287, filed on Jan. 6, 2015; the entire contents of which are incorporated herein by reference.

### FIELD

Embodiments described herein relate generally to a method for manufacturing a semiconductor device.

### BACKGROUND

Memory device having a three-dimensional structure has been proposed. In the memory device, memory holes are formed through a stacked body including a plurality of electrode layers functioning as control gates in memory cells. The electrode layers are stacked with an insulating layer between the electrode layers. And a channel film is provided on a sidewall of the memory hole via a charge storage film.

As a contact structure for connecting each of the electrode layers to a control circuit in the three-dimensional memory device, a structure in which the electrode layers are processed into a stair-like shape has been proposed.

As a method for processing the electrode layers into the stair-like shape, a method for alternately repeating slimming a resist film and etching the stacked body including the electrode layers has been proposed. When the number of electrode layers and hence the number of stairs of the stair-shaped portion of the electrode layers increase, the resist film may undesirably disappear with repeating the slimming of the resist film multiple times. Increasing the thickness of the resist film is limited by resolution limit in a lithography process.

### BRIEF DESCRIPTION OF THE DRAWINGS

FIG. 1 is a schematic perspective view of a memory cell array of a semiconductor device of an embodiment;

FIG. 2 is a schematic cross-sectional view of memory cells of the semiconductor device of the embodiment;

FIG. 3 is a schematic cross-sectional view of a stair-shaped contact portion of the semiconductor device of the embodiment; and

FIGS. 4 to 25 are schematic cross-sectional views showing a method for manufacturing the semiconductor device of the embodiment.

### DETAILED DESCRIPTION

According to one embodiment, a method for manufacturing a semiconductor device includes forming a stacked mask on a layer to be processed. The stacked mask has a plurality of intermediate films and a plurality of mask films alternately stacked. The method includes forming a stair-shaped portion in a top-layer first intermediate film among the plurality of intermediate films. The forming the stair-shaped portion includes sliming a top-layer mask film, and etching the first intermediate film exposed by the slimming of the top-layer mask film. The sliming the top-layer mask film and the etching the first intermediate film are repeated multiple times. The method includes forming a first stair-shaped portion in a second intermediate film among the plurality of intermediate films by transferring the stair-shaped portion of an upper intermediate film. The second intermediate film is below the first intermediate film. The method includes forming a second stair-shaped portion following the first stair-shaped portion in the second intermediate film. The forming the second stair-shaped portion includes slimming a mask film immediately above the second intermediate film, and etching the second intermediate film. The slimming the mask film and the etching the second intermediate film are repeated multiple times.

An embodiment will be described below with reference to the drawings. In the drawings, the same elements have the same reference characters.

In the embodiment, a semiconductor memory device having a three-dimensionally structured memory cell array will be described as the semiconductor device.

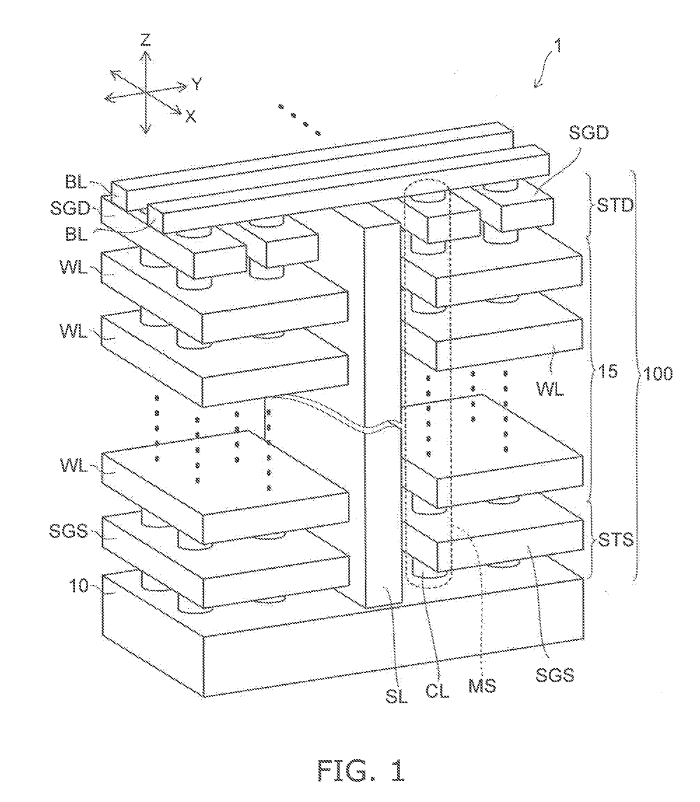

FIG. 1 is a schematic perspective view of a memory cell array 1 of the embodiment. In FIG. 1, no insulating layer is shown for ease of illustration.

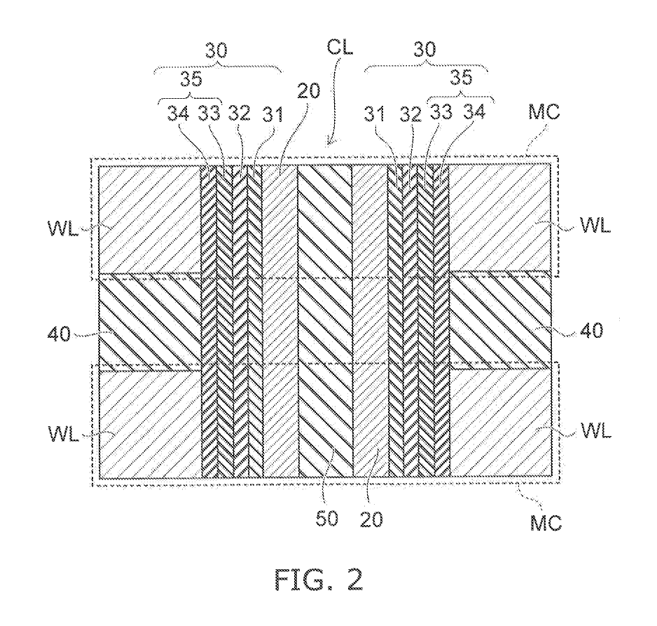

FIG. 2 is a schematic cross-sectional view of memory cells MC of the embodiment,

In FIG. 1, it is assumed that an X-direction (first direction) and a Y-direction (second direction) are two directions parallel to a major surface of a substrate 10 and perpendicular to each other, and that a Z-direction (third direction, stacked direction) is a direction perpendicular to both the X-direction and the Y-direction.

A source-side select gate (lower gate layer) SGS is provided on the substrate 10 via an insulating layer. A stacked body 15, in which electrode layers WL and insulating layers are alternately stacked on each other, is provided on the source-side select gate SGS. The stacked body 15 includes a plurality of electrode layers WL and a plurality of insulating layers. An insulating layer 40 is provided between the electrode layers WL, as shown in FIG. 2. A drain-side select gate (upper gate layer) SGD is provided on the top electrode layer WL via an insulating layer.

Each of the source-side select gate SGS, the drain-side select gate SGD, and the electrode layers WL is a metal layer (layer primarily containing tungsten, for example). Instead, each of the source-side select gate SGS, the drain-side select gate SGD, and the electrode layers WL is, for example, a silicon layer primarily containing silicon, and boron is, for example, doped as an impurity for imparting conductivity into the silicon layer. Still instead, each of the source-side select gate SGS, the drain-side select gate SGD, and the electrode layers WL may contain a metal silicide.

A plurality of bit lines BL (metal films, for example) are provided on the drain-side select gate SGD via an insulating layer.

The drain-side select gate SGD is divided into a plurality of portions in the Y-direction in correspondence with a plurality of columns each of which is formed of columnar portions CL arranged in the X-direction. And each of the divided drain-side select gates SGD extends in the X-direction. The plurality of bit lines BL are separated from each other in the X-direction in correspondence with a plurality of rows each of which is formed of the columnar portions CL arranged in the Y-direction. And each of the bit lines BL extends in the Y-direction.

The plurality of columnar portions CL penetrates a stacked body 100 including the source-side select gate SGS, the stacked body 15 including the plurality of electrode layers WL, and the drain-side select gate SGD. The columnar portions CL extend in the stacked direction of the stacked body 15 (Z-direction). Each of the columnar portions CL is shaped, for example, into a circular column or elliptical column.

The stacked body 100 is divided into a plurality of blocks in the Y-direction. A source layer SL is, for example, provided between the divided blocks.

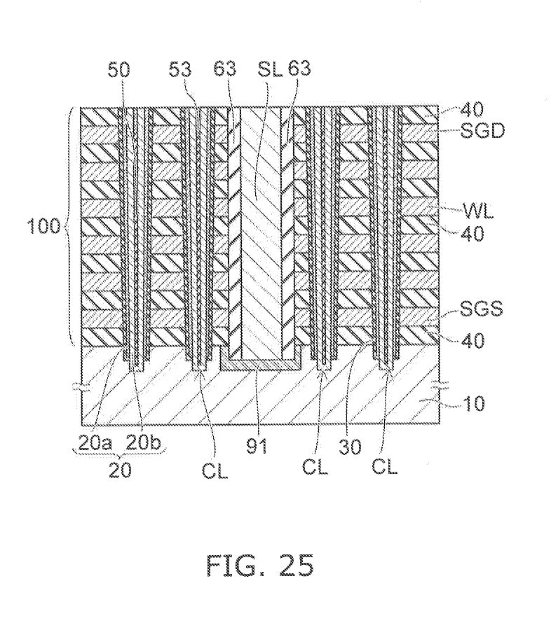

The source layer SL contains a metal (tungsten, for example). The lower end of the source layer SL is connected to the substrate 10. The upper end of the source layer SL is connected to an upper layer interconnect (not shown). An insulating film 63 is provided between the source layer SL and the electrode layers WL, between the source layer SL and the source-side select gate SGS, and between the source layer SL and the drain-side select gate SGD, as shown in FIG. 25, which will be described later.

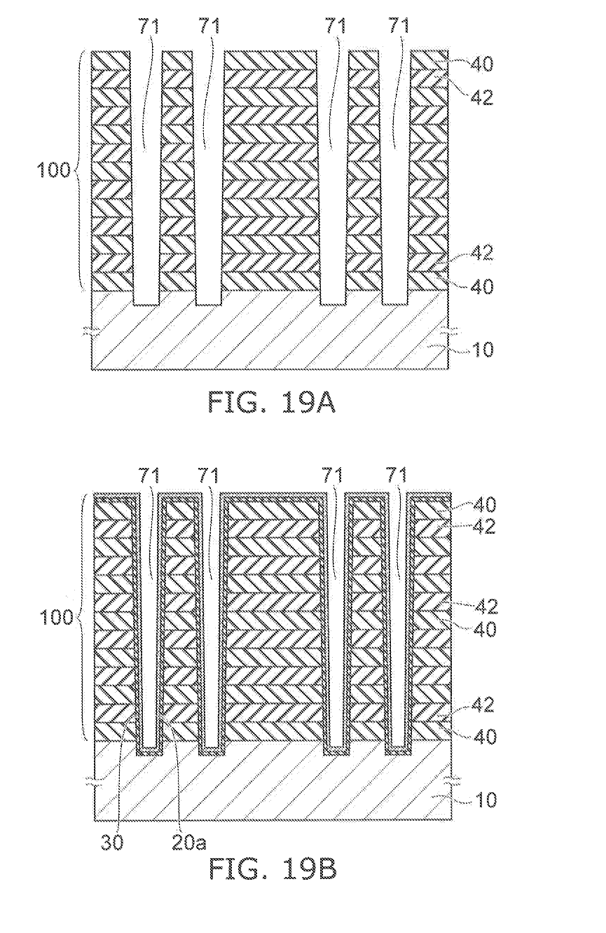

The columnar portions CL are formed in memory holes 71 (shown in FIG. 19A), which are formed in the stacked body 100. A channel film 20, which is shown in FIG. 2, is provided in the form of a semiconductor film or a semiconductor body in each of the memory holes 71. The channel film 20 is, for example, a silicon film primarily containing silicon. The channel film 20 contains substantially no impurity.

The channel film 20 is formed in a tubular shape extending in the stacked direction of the stacked body 100. An upper end portion of the channel film 20 penetrates the drain-side select gate SGD and is connected to a corresponding one of the bit lines BL shown in FIG. 1.

A lower end portion of the channel film 20 penetrates the source-side select gate SGS and is connected to the substrate 10. The lower end of the channel film 20 is electrically connected to the source layer SL via the substrate 10.

A memory film 30 is provided between the sidewall of the memory hole and the channel film 20, as shown in FIG. 2. The memory film 30 has a block insulating film 35, a charge storage film 32, and a tunnel insulating film 31. The memory film 30 is formed in a tubular shape extending in the stacked direction of the stacked body 100.

The block insulating film 35, the charge storage film 32, and the tunnel insulating film 31 are provided between the electrode layers WL and the channel film 20 in this order from the side where the electrode layers WL are present. The block insulating film 35 is in contact with the electrode layers WL. The tunnel insulating film 31 is in contact with the channel film 20. The charge storage film 32 is provided between the block insulating film 35 and the tunnel insulating film 31.

The memory film 30 surrounds the outer circumference of the channel film 20. The electrode layers WL surround the outer circumference of the channel film 20 via the memory film 30. A core insulating film 50 is provided inside the channel film 20.

Each of the electrode layers WL functions as a control gate of the corresponding memory cell MC. The charge storage film 32 functions as a data memory layer that stores charge injected from the channel film 20. Each of the memory cells MC is formed at the portion where the channel film 20 and each of the electrode layers WL intersect each other and has a vertical transistor structure in which the channel film 20 is surrounded by the control gate.

The semiconductor device of the embodiment is a nonvolatile semiconductor memory device freely capable of electrical data erase operation and programming and capable of holding stored data even when the electric power is turned off.

Each of the memory cells MC is, for example, a charge-trap memory cell. The charge storage film 32 has a large number of trap sites that trap charge and includes, for example, a silicon nitride film.

The tunnel insulating film 31 serves as a potential barrier when charge is injected from the channel film 20 to the charge storage film 32 or when charge stored in the charge storage film 32 diffuses into the channel film 20. The tunnel insulating film 31 includes, for example, a silicon oxide film. The tunnel insulating film 31 may instead be formed of a stacked film having a structure in which a pair of silicon oxide films sandwich a silicon nitride film (ONO film). A tunnel insulating film 31 formed of an ONO film allows data erase operation by using a low electric field as compared with a tunnel insulating film 31 formed of a single-layer silicon oxide film.

The block insulating film 35 prevents the charge stored in the charge storage film 32 from diffusing into the electrode layers WL. The block insulating film 35 has a cap film 34 in contact with the electrode layers WL, and a block film 33 provided between the cap film 34 and the charge storage film 32.

The block film 33 is, for example, a silicon oxide film. The cap film 34 is a film having dielectric constant higher than that of a silicon oxide film, such as a silicon nitride film, an aluminum oxide film, a hafnium oxide film, or an yttrium oxide film. Such a cap film 34 in contact with the electrode layers WL, allows suppression of backward tunnel electrons injected from the electrode layers WL at the time of data erase operation.

A drain-side select transistor STD is provided at upper end portions of the columnar portions CL, and a source-side select transistor STS is provided at lower end portions of the columnar portions CL, as shown in FIG. 1.

Each of the memory cell MC, the drain-side select transistor STD, and the source-side select transistor STS is a vertical transistor in which current flows in the stacked direction of the stacked body 100 (Z-direction).

The drain-side select gate SGD functions as a gate electrode (control gate) of the drain-side select transistor STD. An insulating film that functions as a gate insulating film of the drain-side select transistor STD is provided between the drain-side select gate SGD and the channel film 20.

The source-side select gate SGS functions as a gate electrode (control gate) of the source-side select transistor STS. An insulating film that functions as a gate insulating film of the source-side select transistor STS is provided between the source-side select gate SGS and the channel film 20.

A plurality of memory cells MC, which use the electrode layers WL as the control gates, are provided between the drain-side select transistor STD and the source-side select transistor STS. The plurality of memory cells MC, the drain-side select transistor STD, and the source-side select transistor STS are connected to each other in series via the channel film 20 to form a single memory string MS. Arranging a plurality of memory strings MS in the X-direction and the Y-direction provides a plurality of memory cells MC three-dimensionally arranged in the X-direction, the Y-direction, and the Z-direction.

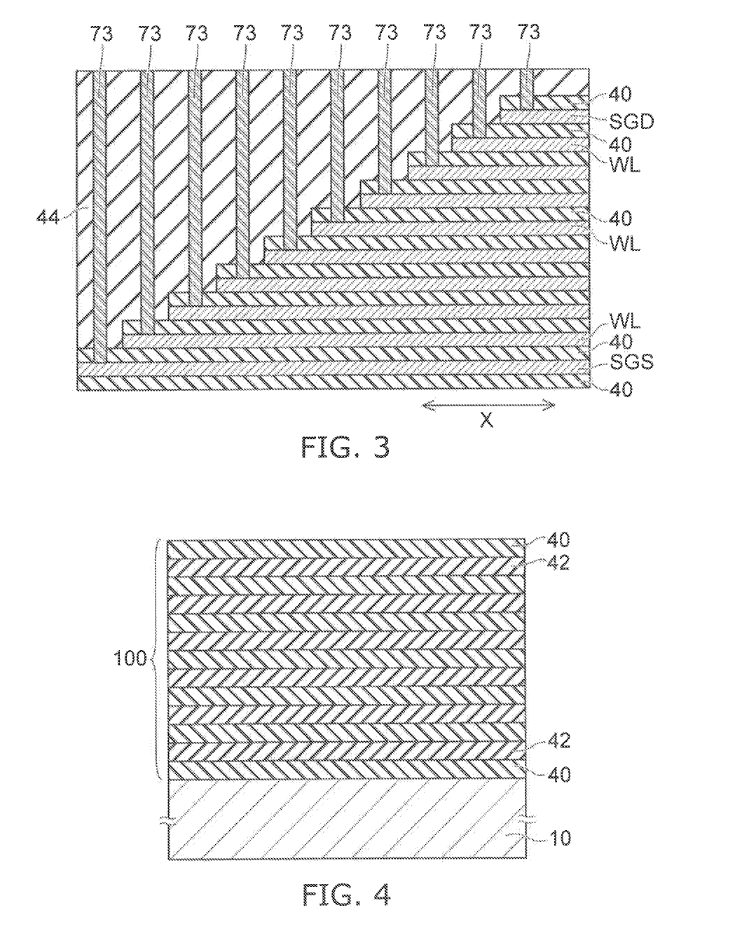

FIG. 3 is a schematic cross-sectional view of a stair-shaped contact portion of the semiconductor device of the embodiment.

Part of the stacked body 100, which includes the source-side select gate SGS, the drain-side select gate SGD, and the plurality of electrode layers WL, is processed into a stair-like shape, as shown in FIG. 3. The X-direction shown in FIG. 3 corresponds to the X-direction shown in FIG. 1.

The source-side select gate SGS, the drain-side select gate SGD, and the electrode layers WL are processed into a stair-like shape along the X-direction. The source-side select gate SGS is located at the bottom stair of the stair-shaped portion, and the drain-side select gate SGD is located at the top stair of the stair-shaped portion.

The insulating layers 40 are provided on the stairs of the source-side select gate SGS, the drain-side select gate SGD, and the electrode layers WL, and the insulating layers 40 are also processed into a stair-like shape along the X-direction.

An interlayer insulating film 44 is provided on the stair-shaped portion. The interlayer insulating film 44 covers the stair-shaped portion. A plurality of vias or plugs 73 are provided on the stair-shaped portion. The vias 73 extend upward from the stair-shaped portion. The vias 73 penetrate the interlayer insulating film 44 and the insulating layers 40 on the stairs and reach the source-side select gate SGS, the drain-side select gate SGD, and the electrode layers WL at the respective stairs.

Each of the vies 73 is formed, for example, of a conductive film containing a metal. The vies 73 are electrically connected to the source-side select gate SGS, the drain-side select gate SGD, and the electrode layer WL at the respective stairs. Each of the vies 73 is connected to the upper layer interconnect (not shown) provided on the stacked body 100.

The source-side select gate SGS, the drain-side select gate SGD, and the electrode layers WL in the stair-shaped contact portion are integrated with the source-side select gate SGS, the drain-side select gate SGD, and the electrode layers WL in the memory cell array 1.

The source-side select gate SGS, the drain-side select gate SGD, and the electrode layers WL in the memory cell array 1 are therefore connected to the upper layer interconnect via the vies 73 in the stair-shaped contact portion. The upper layer interconnect is connected to a control circuit formed, for example, on the surface of the substrate 10. The control circuit controls the operation of the memory cell array 1.

As a method for processing the plurality of electrode layers WL into a stair-like shape, there is a proposed method for repeating the following processes multiple times: a slimming process of reducing the planar size of a resist film; and the process of etching the insulating layer 40 and the electrode layer WL on a stair basis by using the resist film as a mask. The resist film is isotropically etched so that the planar size and the thickness thereof are reduced.

The thickness of the resist film is limited by resolution limit in a lithography process and, for example, is about several micrometers. On the other hand, the width of a terrace portion of each of the stairs of the stair-shaped portion (width in X-direction in FIG. 3), that is, the amount of recession of the resist film per slimming operation (amount of slimming) ranges from about several hundred nanometers to about one micrometer. As the number of stacked electrode layers WL and hence the number of resist film slimming operations increase, the resist film may undesirably disappear before all the electrode layers WL undergo the stair shaping.

To avoid the situation, the following process may be proposed. The process includes removing a thin, left resist film by an ashing process in the course of the stair shaping; treating the stair-shaped portion with a chemical solution; applying a resist film again; and patterning the resist film by a lithography process. And slimming the resist film and etching the stacked film are repeated in the same manner as before.

As the number of stairs of the electrode layers WL increases, however, the number of cycles of the repeated removing of the left resist film, chemical solution treatment, and patterning of a new resist film increases, resulting in a large increase in the number of processes and an increase in cost.

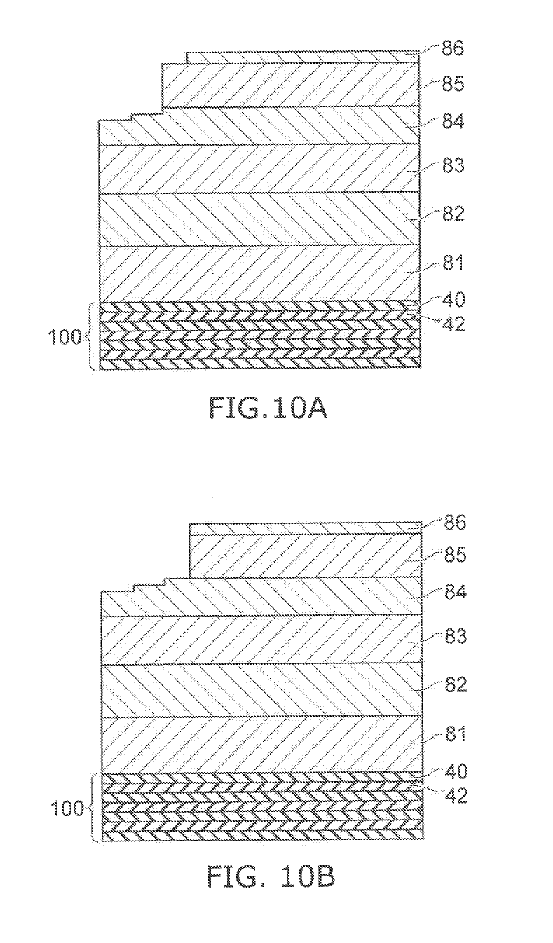

FIG. 4 to FIG. 18B are schematic cross-sectional views showing a method for forming the stair-shaped contact portion in the semiconductor device of the embodiment.

The stacked body 100 is formed, as a layer to be processed, on the substrate 10, as shown in FIG. 4. The stacked body 100 has a plurality of sacrifice layers (first layers) 42 and a plurality of insulating layers (second layers) 40. The substrate 10 is a semiconductor substrate and is, for example, a silicon substrate.

The insulating layers 40 and the sacrifice layers 42 are alternately formed on the substrate 10. The number of stacked sacrifice layers 42 and insulating layers 40 is not limited to the number of layers shown in FIG. 4. The top layer of the stacked body 100 is, for example, one of the insulating layers 40.

Each of the insulating layers 40 is, for example, a silicon oxide film. Each of the sacrifice layers 42 is made of a material different from the material of the insulating layers 40 and is, for example, a silicon nitride film. The sacrifice layers 42 will be replaced with the select gates SGS and SGD and the electrode layers WL in a subsequent process.

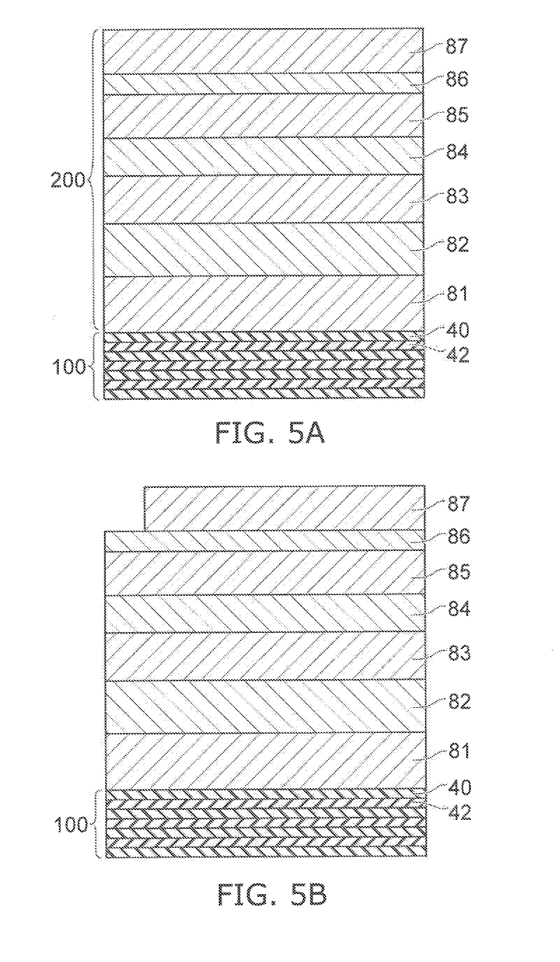

A stacked mask 200 is formed on the stacked body 100, as shown in FIG. 5A. The stacked mask 200 has a first mask film 81 as a foundation mask film, a plurality of second mask films 83, 85, and 87, and a plurality of intermediate films 82, 84, and 86. The number of second mask films 83, 85, and 87 and intermediate films 82, 84, and 86 is not limited to the number of films shown in FIG. 5A.

The first mask film 81 is formed on the stacked body 100. The plurality of second mask films 83, 85, and 87 are formed above the first mask film 81. The intermediate film 82 is formed between the first mask film 81 and the second mask film 83 which is the lowermost second mask film. The intermediate film 84 is formed between the second mask film 83 and the second mask film 85, and the intermediate film 86 is formed between the second mask film 85 and the second mask film 87.

The first mask film 81 is made of a material different from the material of the stacked body 100 and is, for example, an organic film primarily containing carbon.

Each of the second mask films 83, 85, and 87 is made of the same material as that of the first mask film 81 and is, for example, an organic film primarily containing carbon. Among the second mask films, the second mask film 87 which is the top second mask film, is a film containing a photosensitive agent or what is called a resist film,

The second mask films 83, 85, and 87 may instead be made of a material different from the material of the first mask film 81. Allowing the second mask films 83, 85, and 87 and the first mask film 81 to be made of the same material is favorable from a viewpoint of process integration.

The intermediate films 82, 84, and 86 are made of a material different from the material of the first mask film 81 and the second mask films 83, 85, and 87 and are each, for example, a silicon oxide film.

Among the plurality of intermediate films 82, 84, and 86, a lower-layer-side intermediate film is thicker than an upper-layer-side intermediate film. More specifically, among the plurality of intermediate films 82, 84, and 86, a lower intermediate film is thicker.

The lower intermediate film is thicker in such a way that the intermediate films 84 and 82 have thicknesses that are roughly integer multiples of the thickness of the top intermediate film 86. For example, the intermediate film 86 has a thickness of about 100 nm, the intermediate film 84 has a thickness of about 200 nm, and the intermediate film 82 has a thickness of about 300 nm,

The first mask film 81 is roughly as thick as the second mask films 83, 85, and 87. The second mask films 87, 85, and 83 are slimmed and used as masks to shape the intermediate films 86, 84, and 82, which are below the second mask films 87, 85, and 83, into the stair-shaped portion, as will be described later. The second mask films 87, 85, and 83 have an enough thickness not to disappear before the intermediate films 86, 84, and 82, which are below the second mask films 87, 85, and 83, are processed into the stair-shaped portion. On the other hand, when the second mask films 87, 85, and 83 are thicker than necessary, it is difficult to control the dimensions thereof at the time of slimming in some cases.

A stair-shaped portion sequentially transferred from the upper films is formed in the first mask film 81. The first mask film 81 has an enough thickness to allow the formation of the stair-shaped portion.

As described above, each of the first mask film 81 and the second mask films 87, 85, and 83 is desired to have an appropriate thickness. According to the embodiment, the thickness of each of the first mask film 81 and the second mask films 83, 85, and 87 is, for example, 5 μm or more but 10 μm or less.

The second mask film (resist film) 87, which is the top second mask film, is patterned by light exposure and development. Among the plurality of intermediate films 86, 84, and 82, the top intermediate film 86 formed immediately below the top second mask film 87, is called a first intermediate film. And each of the intermediate films 84 and 82 formed below the first intermediate film 86, is called a second intermediate film.

The top second mask film 87 may instead be a lower-layer-side film of a multilayer resist. In this case, the second mask film 87 needs to contain no photosensitive agent, and after an upper-layer-side resist film is exposed to light, developed, and patterned, the resultant pattern of the resist film can be transferred to pattern the lower-layer-side second mask film 87.

After the second mask film 87 is patterned, part of the first intermediate film 86 is exposed, as shown in FIG. 5B.

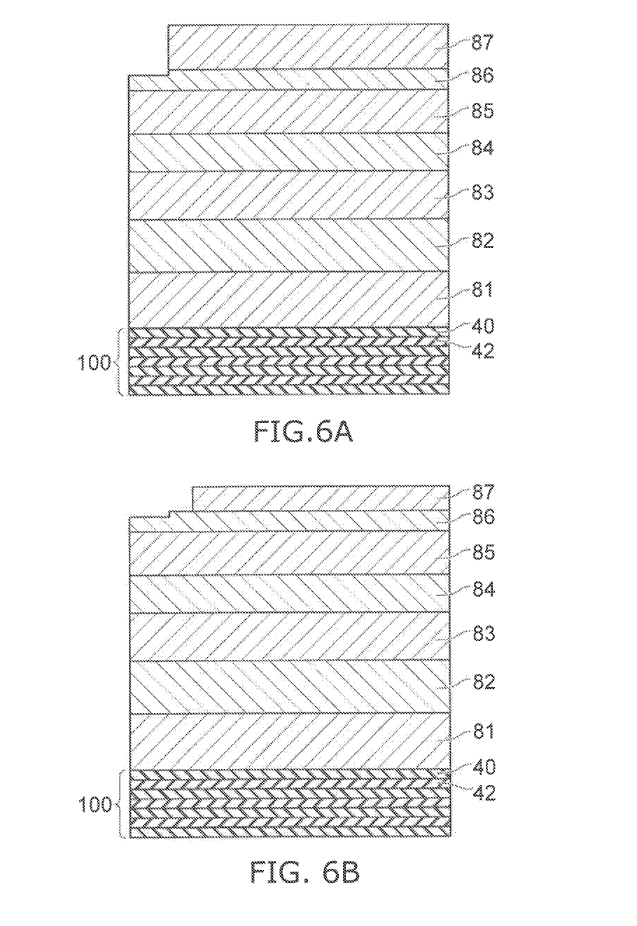

The second mask film 87 is then used as a mask to etch the exposed portion of the first intermediate film 86 in the thickness direction, for example, by using an RIE (reactive ion etching) method, which is anisotropic dry etching. For example, the first intermediate film 86, which is a silicon oxide film, is etched by using a fluorocarbon-based gas. The exposed portion of the first intermediate film 86 is etched back in the thickness direction so that a step is formed in the first intermediate film 86, as shown in FIG. 6A. A fluorocarbon-based gas is, for example, used also in the RIE of the intermediate films 84 and 82 in subsequent processes.

The second mask film 87 is then slimmed in isotropic dry etching. For example, an ashing process using a gas containing oxygen is carried out on the second mask film 87. The ashing process using a gas containing oxygen is, for example, also applied to slim the second mask films 85 and 83 in subsequent processes.

The second mask film 87 is so isotropically etched in the planar direction and the thickness direction that the exposed region of the first intermediate film 86 or the region thereof not covered with the second mask film 87 increases, as shown in FIG. 6B.

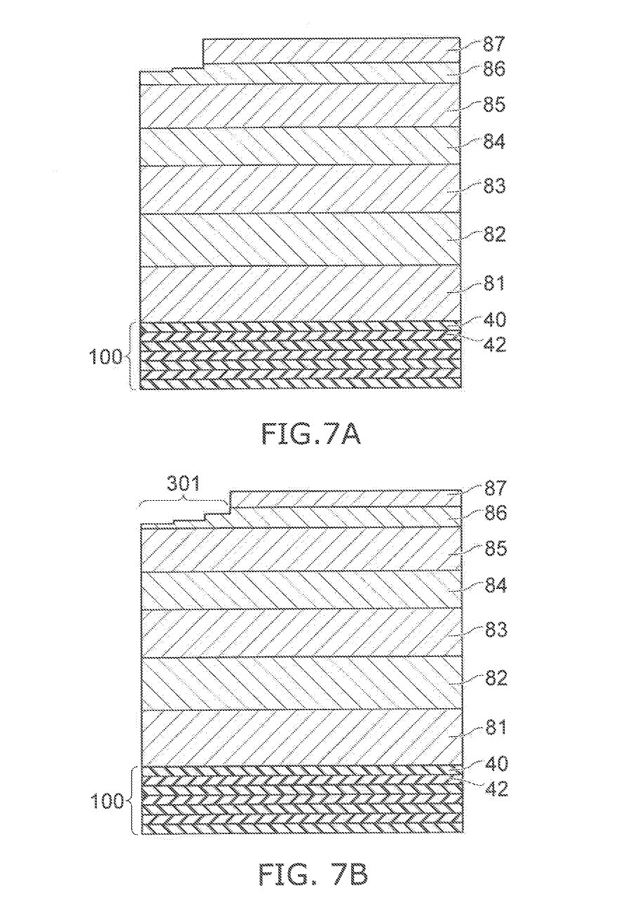

The thus slimmed second mask film 87 is used as a mask to perform further RIE on the first intermediate film 86. The surface of the newly exposed portion of the first intermediate film 86 is etched back from the surface of the portion thereof covered with the second mask film 87, and the surface of the portion having already receded in the previous RIE also further recedes downward, as shown in FIG. 7A. That is, a step is formed in the exposed portion of the first intermediate film 86 or the portion thereof not covered with the second mask film 87.

Further, the slimming of the second mask film 87 and the RIE of the first intermediate film 86 using the slimmed second mask film 87 as a mask are repeated. As a result, a stair-shaped portion 301 is formed in the exposed portion of the first intermediate film 86 or the portion thereof not covered with the second mask film 87, as shown in FIG. 7B. At this point, the second mask film 85 formed immediately below the first intermediate film 86 is not exposed.

The second mask film 85, which is formed immediately below the first intermediate film 86, is used to transfer the stair-shaped portion 301 of the first intermediate film 86 to the second intermediate film 84 below the second mask film 85.

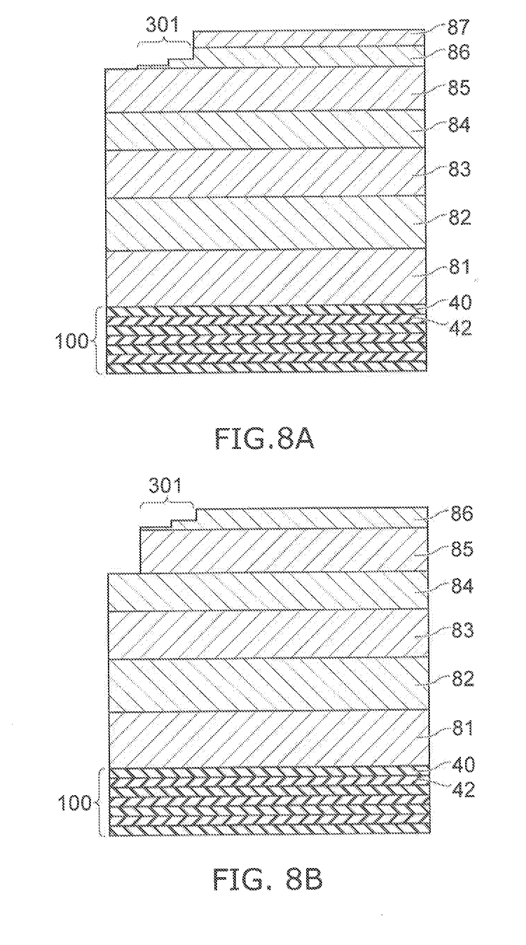

The entire exposed stair-shaped portion 301 that is not covered with the second mask film 87 is etched back in the thickness direction by using the RIE method. The thinnest portion of the stair-shaped portion 301 (bottom stair portion) therefore disappears, and part of the second mask film 85 is exposed, as shown in FIG. 8A.

The exposed portion of the second mask film 85 is so anisotropically etched in the thickness direction, for example, by using the RIE method using oxygen gas that part of the intermediate film 84 is exposed, as shown in FIG. 8B. In this process, the intermediate film 86 serves as a mask so that the portion of the second mask film 85 that is covered with the intermediate film 86 is not etched.

At the point shown in FIG. 8A, the second mask film 87 left on the intermediate film 86 is thinner than the second mask film 85, and the second mask film 87 disappears at the time of the etching of part of the second mask film 85.

The removal of the second mask film 87 exposes the entire surface of the intermediate film 86, as shown in FIG. 8B. The intermediate film 86 and the exposed portion of the intermediate film 84, which was exposed at the time of the removal of part of the second mask film 85 described above, are etched back in the thickness direction using the RIE method.

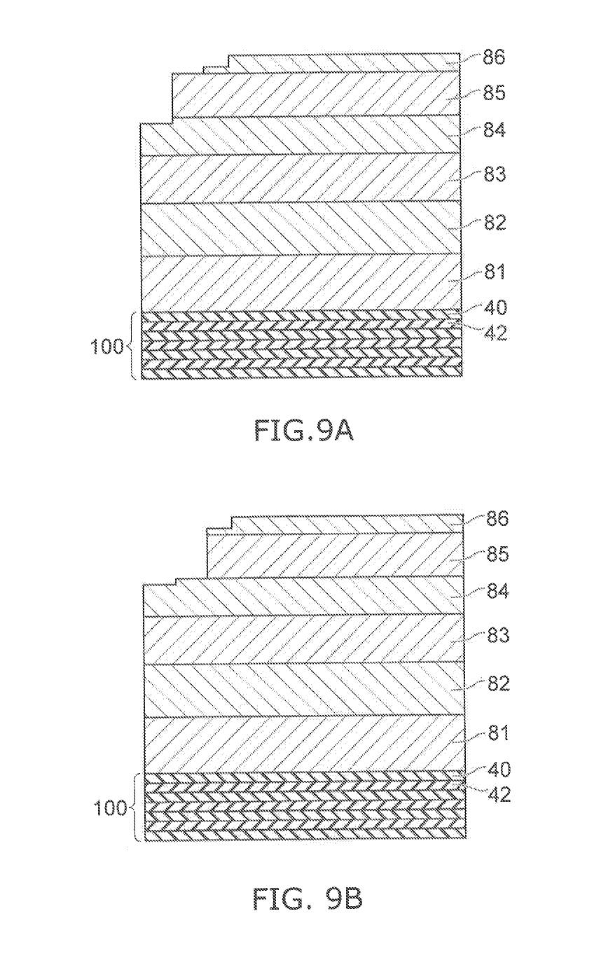

The thinnest bottom stair portion of the left stair-shaped portion 301 of the intermediate film 86 disappears, and the exposed portion of the intermediate film 84 or the portion thereof not covered with the second mask film 85 is etched back in the thickness direction, as shown in FIG. 9A. A step is thus formed in the intermediate film 84.

Thereafter, the removal of the exposed portion of the second mask film 85 or the portion thereof not covered with the intermediate film 86 and the etching back of the intermediate films 86 and 84 are repeated in the same manner as before, as shown in FIG. 9B to FIG. 11A.

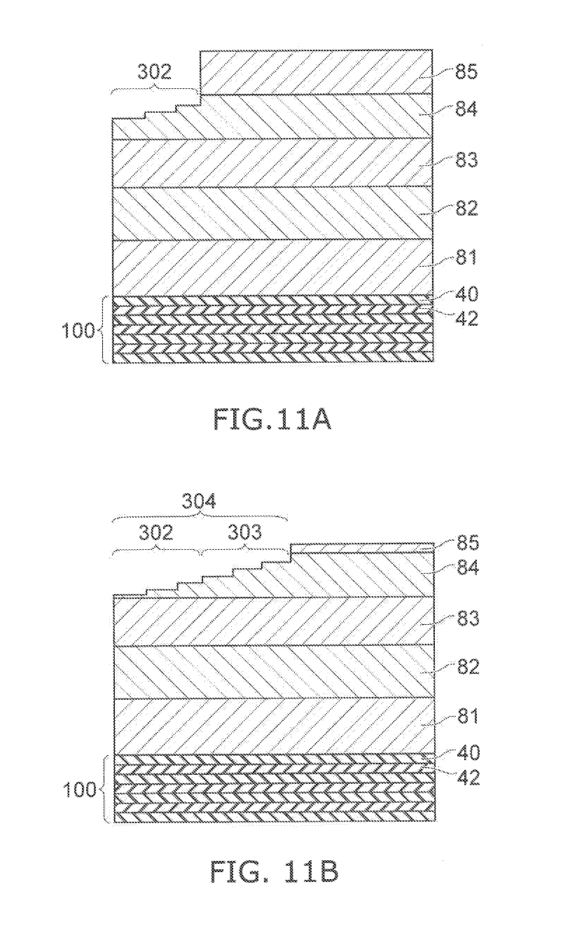

As a result, a stair-shaped portion 302 having the same number of stairs as the number of stairs of the stair-shaped portion 301 formed in the intermediate film 86, which is located above the intermediate film 84, and shown in FIG. 7B is formed in the intermediate film 84, which is located below the intermediate film 86, as shown in FIG. 11A.

Appropriately setting the thickness of the intermediate film 86, which is located above, and the thickness of the intermediate film 84, which is located below, allows not only the stair-shaped portion 302 to be formed with the second mask film 83 below the intermediate film 84 not exposed but also the intermediate film 86 on the second mask film 85 to disappear.

Instead, after the stair-shaped portion 302 is formed, the intermediate film 86 left on the second mask film 85 can be etched away in a separate process.

Thereafter, the slimming of the second mask film 85 and the RIE of the intermediate film 84 using the slimmed second mask film 85 as a mask are repeated multiple times.

As a result, the stair-shaped portion (first stair-shaped portion) 302 transferred from the intermediate film 86, which is located above, is followed by a second stair-shaped portion 303, as shown in FIG. 11B. The second stair-shaped portion 303 is formed by repeating the following processes multiple times: the process of slimming the second mask film 85; and the process of performing RIE on the intermediate film 84 by using the slimmed second mask film 85 as a mask. The second stair-shaped portion 303 is formed on the side of the upper stair of the first stair-shaped portion 302.

A stair-shaped portion 304 (first stair-shaped portion 302 and second stair-shaped portion 303) is formed in the intermediate film 84. The stair-shaped portion 304 has a larger number of stairs than the number of stairs of the stair-shaped portion 301 formed in the intermediate film 86, which is located above the intermediate film 84, and shown in FIG. 7B, For example, the stair-shaped portion 304 formed in the intermediate film 84 has stairs the number of which is twice the number of stairs of the stair-shaped portion 301 of the intermediate film 86, which is located above the intermediate film 84.

Thereafter; the same processes shown in FIG. 8A to FIG. 11A are repeated. That is, the second mask film 83 formed immediately below the intermediate film 84 is used to transfer the stair-shaped portion 304 of the intermediate film 84 to the intermediate film 82 below the second mask film 83.

The entire exposed stair-shaped portion 304 that is not covered with the second mask film 85 is etched back in the thickness direction. The thinnest portion of the stair-shaped portion 304 (bottom stair portion) disappears, and part of the second mask film 83 is exposed.

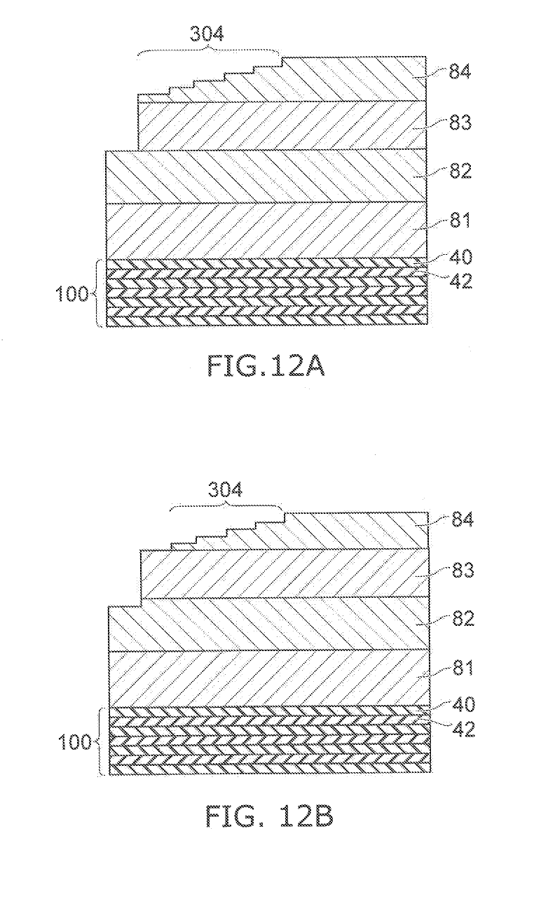

The exposed portion of the second mask film 83 is so anisotropically etched in the thickness direction, for example, by using the RIE method using oxygen gas that part of the intermediate film 82 is exposed, as shown in FIG. 12A. In this process, the portion of the second mask film 83 that is covered with the intermediate film 84 is not etched.

At the point shown in FIG. 118, the second mask film 85 left on the intermediate film 84 is thinner than the second mask film 83, and the second mask film 85 disappears at the time of the etching of part of the second mask film 83.

The removal of the second mask film 85 exposes the entire surface of the intermediate film 84, as shown in FIG. 12A. The intermediate film 84 and the exposed portion of the intermediate film 82, which was exposed at the time of the removal of part of the second mask film 83 described above, are etched back in the thickness direction using the RIE method.

The thinnest bottom stair portion of the left stair-shaped portion 304 of the intermediate film 84 disappears, and the exposed portion of the intermediate film 82 or the portion thereof not covered with the second mask film 83 is etched back in the thickness direction, as shown in FIG. 12B. A step is thus formed in the intermediate film 82.

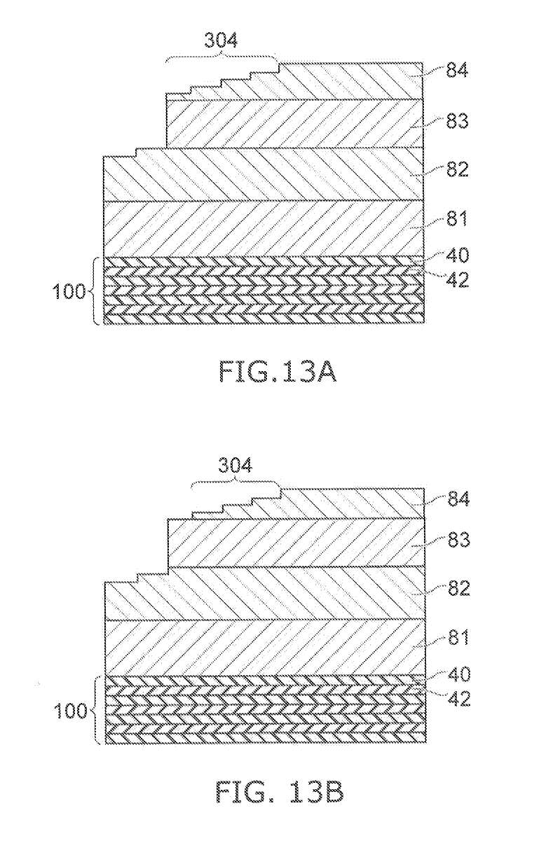

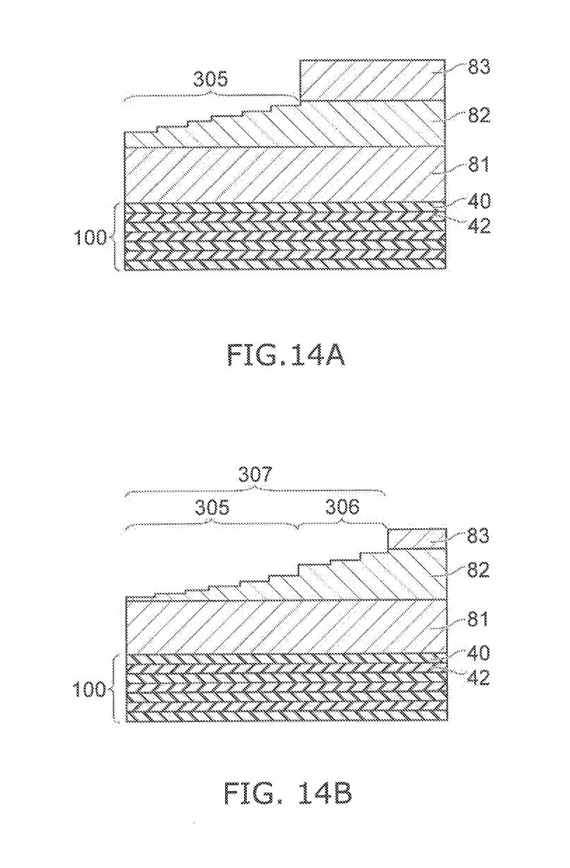

Thereafter, the removal of the exposed portion of the second mask film 83 or the portion thereof not covered with the intermediate film 84 and the etching back of the intermediate film 84 are repeated multiple time, as shown in FIG. 13A to FIG. 14A.

As a result, a stair-shaped portion 305 having the same number of stairs as the number of stairs of the stair-shaped portion 304 formed in the intermediate film 84, which is located above the intermediate film 82, and shown in FIG. 11B is formed in the intermediate film 82, which is located below the intermediate film 84, as shown in FIG. 14A.

Appropriately setting the thickness of the intermediate film 84, which is located above, and the thickness of the intermediate film 82, which is located below, allows not only the stair-shaped portion 305 to be formed with the first mask film 81 below the intermediate film 82 not exposed but also the intermediate film 84 on the second mask film 83 to disappear.

Instead, after the stair-shaped portion 305 is formed, the intermediate film 84 left on the second mask film 83 can be etched away in a separate process.

Thereafter, the slimming of the second mask film 83 and the RIE of the intermediate film 82 using the slimmed second mask film 83 as a mask are repeated multiple times.

As a result, the stair-shaped portion (first stair-shaped portion) 305 transferred from the intermediate film 84, which is located above, is followed by a second stair-shaped portion 306, as shown in FIG. 14B. The second stair-shaped portion 306 is formed by repeating the following processes multiple times: the process of slimming the second mask film 83; and the process of performing RIE on the intermediate film 82 by using the slimmed second mask film 83 as a mask. The second stair-shaped portion 306 is formed on the side of the upper stair of the first stair-shaped portion 305.

A stair-shaped portion 307 (first stair-shaped portion 305 and second stair-shaped portion 306) is formed in the intermediate film 82. The stair-shaped portion 307 has a larger number of stairs than the number of stairs of the stair-shaped portion 304 formed in the intermediate film 84, which is located above the intermediate film 82, and shown in FIG. 11B.

The number of stairs in the stair-shaped portions 301, 304, and 307 formed in the intermediate films 86, 84, and 82 increases in this order or the number of stairs in a lower layer is greater than the number of stairs in an upper layer. The stair-shaped portions 304 and 307, which have stairs the numbers of which are integer multiples of the number of stairs of the stair-shaped portion 301 formed in the intermediate film (first intermediate film) 86, are formed in the intermediate films (second intermediate films) 84 and 82, which are located below the intermediate film (first intermediate film) 86, which is the top intermediate film.

A lower intermediate film is therefore thicker in such a way that the intermediate films 84 and 82 have thicknesses that are roughly integer multiples of the thickness of the top intermediate film 86.

The stair-shaped portion 307 (first stair-shaped portion 305 and second stair-shaped portion 306) of the lowermost intermediate film 82, is then transferred to the first mask film 81.

The entire exposed stair-shaped portion 307 that is not covered with the second mask film 83 is etched back in the thickness direction. The thinnest portion of the stair-shaped portion 307 (bottom stair portion) disappears, and part of the first mask film 81 is exposed.

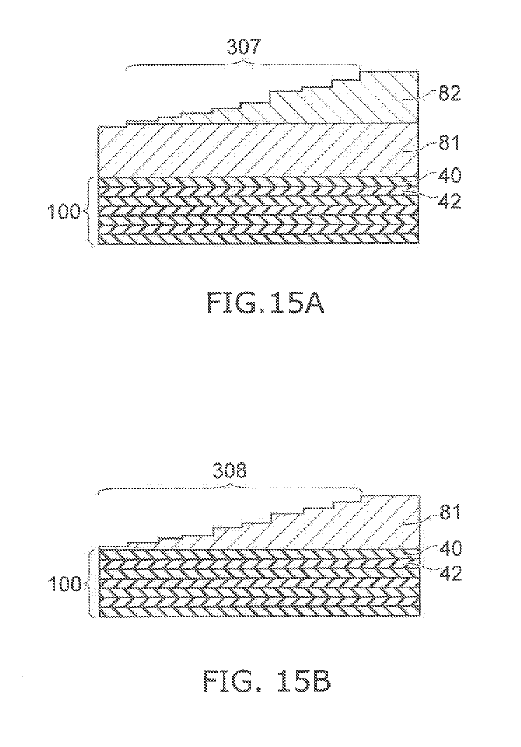

The exposed portion of the first mask film 81 is anisotropically etched back in the thickness direction, for example, by using the PIE method using oxygen gas so that a step is formed in the first mask film 81, as shown in FIG. 15A.

The remaining stair-shaped portion 307 is so etched back again that the bottom stair portion thereof disappears and the exposed region of the first mask film 81 widens accordingly. The exposed portion of the first mask film 81 is then etched back in the thickness direction by using the RIE method.

Thereafter; the following processes are repeated multiple time the process of removing the bottom stair portion of the stair-shaped portion 307 by etching back the stair-shaped portion 307 to widen the exposed region of the first mask film 81; and the process of causing the exposed portion of the first mask film 81 to etch back in the thickness direction.

As a result, a stair-shaped portion 308 is formed in the first mask film 81, as shown in FIG. 15B. The stair-shaped portion 308 transferred to the first mask film 81 has the same number of stairs as the number of stairs of the stair-shaped portion 307 formed in the lowermost intermediate film 82. No slimming is performed on the first mask film 81.

As the RIE of the first mask film 81 is repeated, the second mask film 83 left on the intermediate film 82 disappears.

The stair-shaped portion 308 of the first mask film 81 is then transferred to the stacked body 100 to process the plurality of first layers 42 into a stair-like shape. The first mask film 81, which is made of a material different from the material of the stacked body 100, serves as a mask when the stacked body 100 is etched into a stair-like shape.

When the stacked body 100 is made of a material different from the material of the lowermost intermediate film 82, the first mask film 81 can be omitted. That is, the stair-shaped portion 307 of the intermediate film 82 can be directly transferred to the stacked body 100 via no first mask film 81.

The entire stair-shaped portion 308 of the first mask film 81 is etched back in the thickness direction using the RIE method. The thinnest portion of the stair-shaped portion 308 (bottom stair portion) disappears, and part of the stacked body 100 is exposed. For example, part of the top insulating layer 40 of the stacked body 100 is exposed.

The exposed portion of the stacked body 100 is anisotropically etched back in the thickness direction, for example, by using the RIE method using a fluorocarbon-based gas.

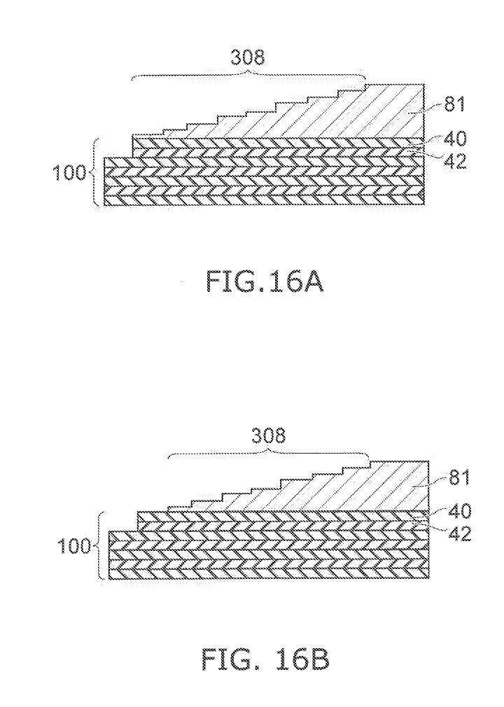

The insulating layers 40 and the sacrifice layers 42 in the exposed portion of the stacked body 100 are removed one layer at a time, as shown in FIG. 16A.

The remaining stair-shaped portion 308 is then etched back again so that the bottom stair portion thereof disappears and the exposed region of the stacked body 100 widens accordingly, as shown in FIG. 16B. The exposed portion of the stacked body 100 is then etched back in the thickness direction by using the RIE method.

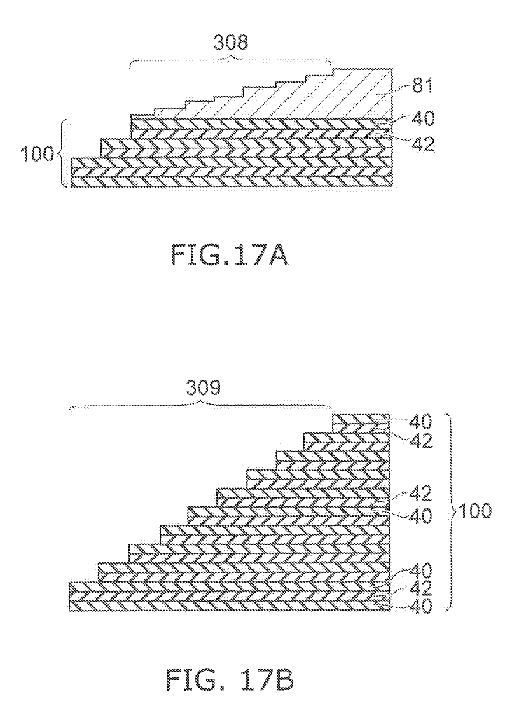

In this process as well, the insulating layers 40 and the sacrifice layers 42 in the exposed portion of the stacked body 100 are removed one layer at a time. The insulating layers 40 and the sacrifice layers 42 in the newly exposed portion are removed one layer at a time, and the insulating layers 40 and the sacrifice layers 42 in the portion where the insulating layers 40 and the sacrifice layers 42 were removed in the previous process are removed again one layer at a time, as shown in FIG. 17A.

Thereafter, the following process are repeated multiple times: the process of removing the bottom stair portion of the stair-shaped portion 308 by etching back the stair-shaped portion 308 to widen the exposed region of the stacked body 100; and the process of removing the insulating layers 40 and the sacrifice layers 42 in the exposed portion one layer at a time.

As a result, the insulating layers 40 and the sacrifice layers 42 are processed into a stair-like shape, and a stair-shaped portion 309 is formed in part of the stacked body 100, as shown in FIG. 17B.

The plurality of sacrifice layers 42 are processed into a stair-like shape, and the insulating layers 40 similarly processed into a stair-like shape are formed on the sacrifice layers 42 at the respective stairs.

The amount of recession of each of the second mask films 87, 85, 83 (amount of slimming) in the planar direction in the processes described above is, for example, about 1 μm, and the width of each of the stairs of the stair-shaped portion 309 (width of protrusion of a lower stair portion from the front end of an upper stair portion) is also about 1 μm.

As described above, the thickness of a resist film is limited by the precision with which the resist film is processed, and it is difficult to repeat slimming of a single thick resist film to form a stair-shaped portion having a large number of stairs in a layer below the resist film, Further, in a method including the following processes carried out multiple times: removing a thin, left resist film by an aching process in the course of the stair shaping; applying a resist film again; patterning the resist film by a lithography process; slimming the resist film; and etching the stacked film in the same manner as before, an increase in the number of stairs of the stair-shaped portion increases the number of cycles of the processes described above, resulting in a large increase in the number of processes and an increase in cost.

In contrast, according to the embodiment, the slimming of the plurality of second mask films 87, 85, and 83 stacked on each other via the intermediate films 86, 84, and 82, is repeated. The thickness of each of the second mask films 87, 85, and 83 is set roughly to a value that does not lower the processing precision.

The stair-shaped portion 301 (FIG. 7B) formed in the intermediate film 86 by slimming the top second mask film 87, is transferred to the intermediate film 84 located below the intermediate film 86, in the form of the stair-shaped portion 302 (FIG. 11A). In the intermediate film 84, the stair-shaped portion 303 (FIG. 11B) formed by slimming the second mask film 85 is formed as well as the stair-shaped portion 302 transferred from the above. The stair-shaped portion 304 (stair-shaped portion 302 and stair-shaped portion 303) formed in the intermediate film 84 is further transferred to the intermediate film 82 located below the intermediate film 84, in the form of the stair-shaped portion 305 (FIG. 14A). In the intermediate film 82, the stair-shaped portion 306 (FIG. 14B) formed by slimming the second mask film 83 is formed as well as the stair-shaped portion 305 transferred from the above. A stair-shaped portion having a desired number of stairs is eventually transferred to the stacked body 100 via the first mask film 81.

According to the embodiment, even when the second mask films 87, 85, and 83 become thin in the slimming process, a process of removing the thinned mask film and forming a new mask film for the following stair shaping is not required, whereby no large increase in the number of processes occurs and cost reduction is achieved.

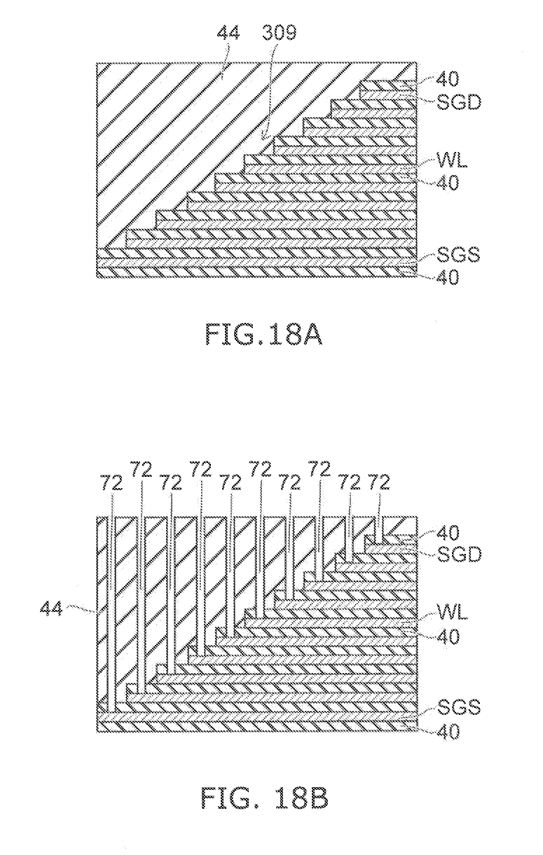

After the stair-shaped portion 309 is formed in the stacked body 100, the interlayer insulating film 44 is formed on the stair-shaped portion 309, as shown in FIG. 18A. The interlayer insulating film 44 covers the stair-shaped portion 309.

After the interlayer insulating film 44 is formed or before the interlayer insulating film 44 is formed, the sacrifice layer 42 are replaced with the electrode layers WL, the drain-side select gate SGD, and the source-side select gate SGS, as will be described later. A structure in which the electrode layers WL, the drain-side select gate SGD, and the source-side select gate SGS are formed in a stair-like shape is thus obtained.

Contact holes 72 are then formed as shown in FIG. 18B. The contact holes 72 penetrate the interlayer insulating film 44 and the insulating layers 40 at the respective stairs, and reach the electrode layers WL at the respective stairs, the drain-side select gate SGD, and the source-side select gate SGS.

A conductive film is formed in each of the contact holes 72, The contact vias (contact plugs) 73 are thus formed, as shown in FIG. 3.

A method for forming the memory cell array 1 will be described with reference to FIG. 19A to FIG. 25.

For example, after the stair-shaped portion 309 described above is formed in the stacked body 100 and the interlayer insulating film 44 is further formed, a plurality of memory holes 71 are formed in a region of the stacked body 100 where the memory cell array 1 is formed, as shown in FIG. 19A. The memory holes 71 are formed by using the RE method using a mask that is not shown. The memory holes 71 penetrate the stacked body 100 and reach the substrate 10.

The memory film 30 is formed on the inner wall (sidewall and bottom wall) of each of the memory holes 71, and a cover film 20a is formed inside the memory film 30, as shown in FIG. 19B.

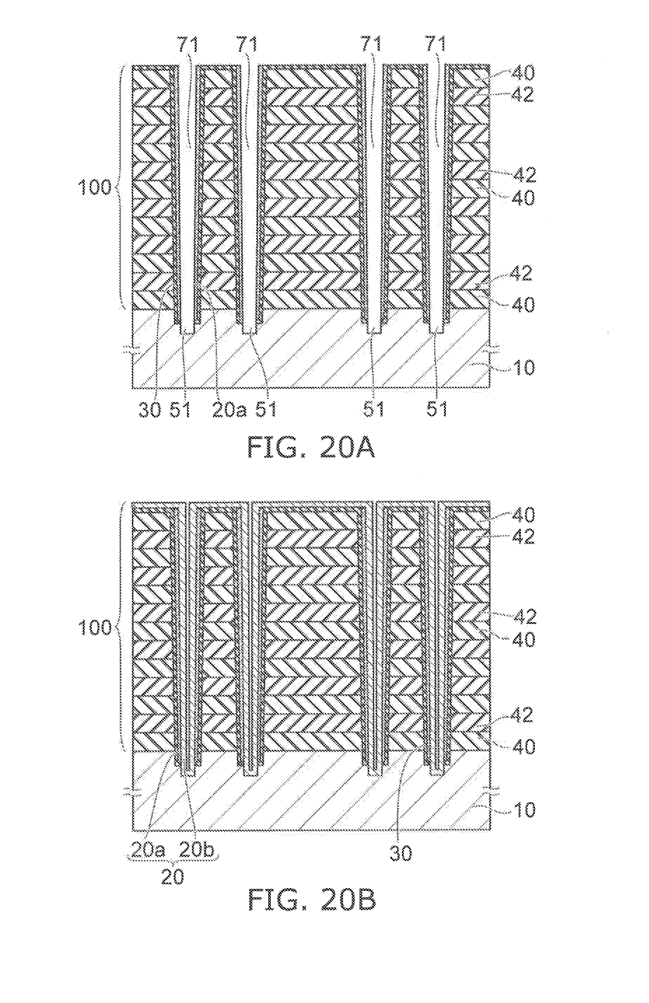

The cover film 20a and the memory film 30 formed at the bottom of each of the memory holes 71 are removed by using the RIE method, and a hole 51 is formed at the bottom of each of the memory holes 71, as shown in FIG. 20A. The substrate 10 forms the side surface and the bottom surface of each of the holes 51.

In the RIE process described above, the memory film 30 formed on the sidewall of each of the memory holes 71 is covered with and protected by the cover film 20a. The memory film 30 formed on the sidewall of each of the memory holes 71 is therefore not damaged in the RIE process.

A channel film 20b is then formed in each of the holes 51 and inside the cover film 20a, as shown in FIG. 208. Each of the cover film 20a and the channel film 20b is formed, for example, of an amorphous silicon film and then annealed into a polycrystalline silicon film. The cover film 20a and the channel film 20b together form each of the channel films 20 described above.

The channel film 20 is electrically connected to the substrate 10 via the channel film 20b formed in the hole 51.

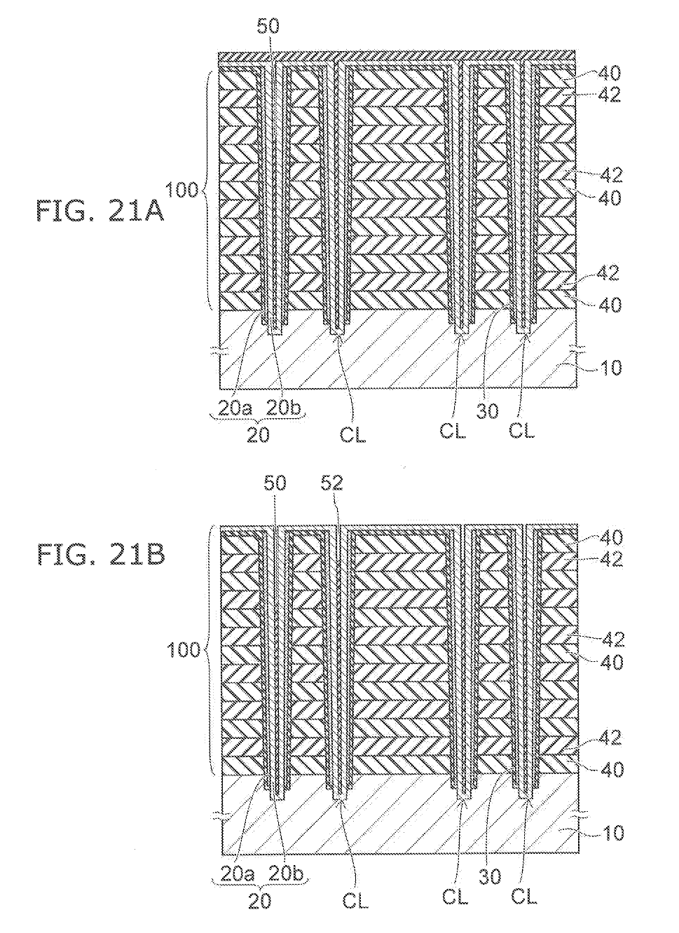

The core insulating film 50 is formed inside the channel film 20b, as shown in FIG. 21A. Each of the columnar portions CL is thus formed. An upper portion of the core insulating film 50 is so etched back that a cavity 52 is formed in an upper portion of the columnar portion CL, as shown in FIG. 21B.

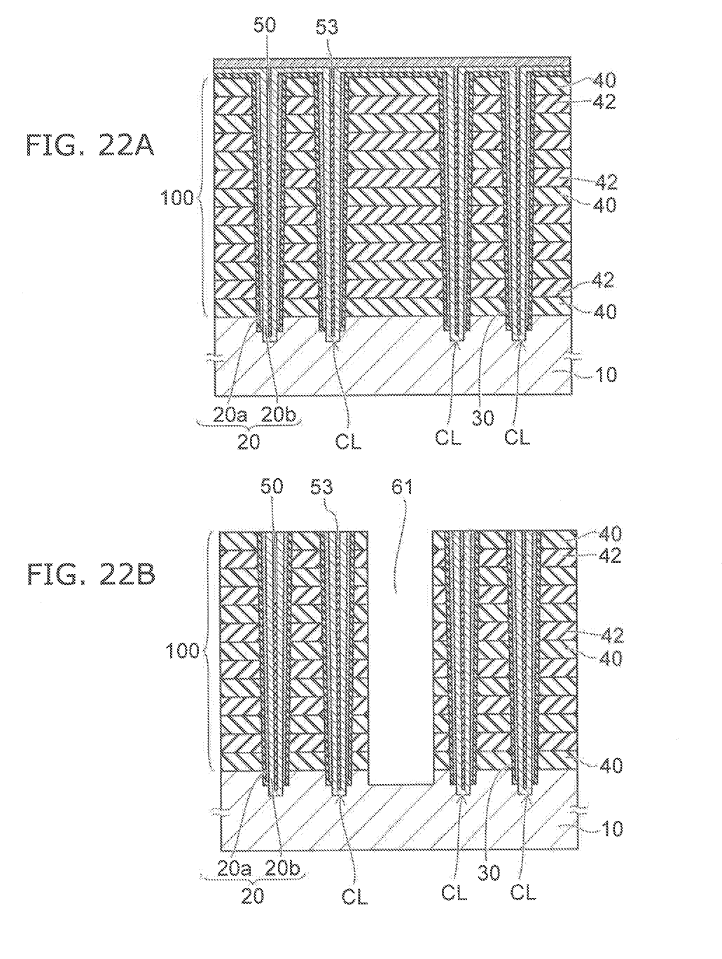

A semiconductor film 53 is buried in each of the cavities 52, as shown in FIG. 22A. The semiconductor film 53 is, for example, a doped silicon film and has an impurity density higher than that of the channel film 20, which is a non-doped silicon film.

In a typical charge-injection memory, data is erased by increasing the potential at the substrate to extract electrons programmed to a charge storage layer, such as a floating gate. There is another erase method in which GIDL (gate induced drain leakage) current produced in a channel at the upper end of the drain-side select gate is used to boost the channel potential of a memory cell.

In the embodiment, the channel potential is boosted by applying a high electric field to the semiconductor film 53 formed in the vicinity of the upper end of the drain-side select gate SGD and having a high impurity density to produce holes and supplying the channel film 20 with the holes. Data is erased by setting the potential at the corresponding electrode layer WL, for example, to the ground potential (0 V) to produce a potential difference between the channel film 20 and the electrode layer WL and extracting electrons in the charge storage film 32 or injecting holes into the charge storage film 32 based on the produced potential difference.

After the semiconductor film 53 is buried in each of the cavities 52, the memory film 30, the channel film 20, and the semiconductor film 53 deposited on the upper surface of the stacked body 100 are removed.

A slit 61 is then formed in the stacked body 100 by using the RIE method using a mask that is not shown, as shown in FIG. 22B. The slit 61 penetrates the stacked body 100 and reaches the substrate 10.

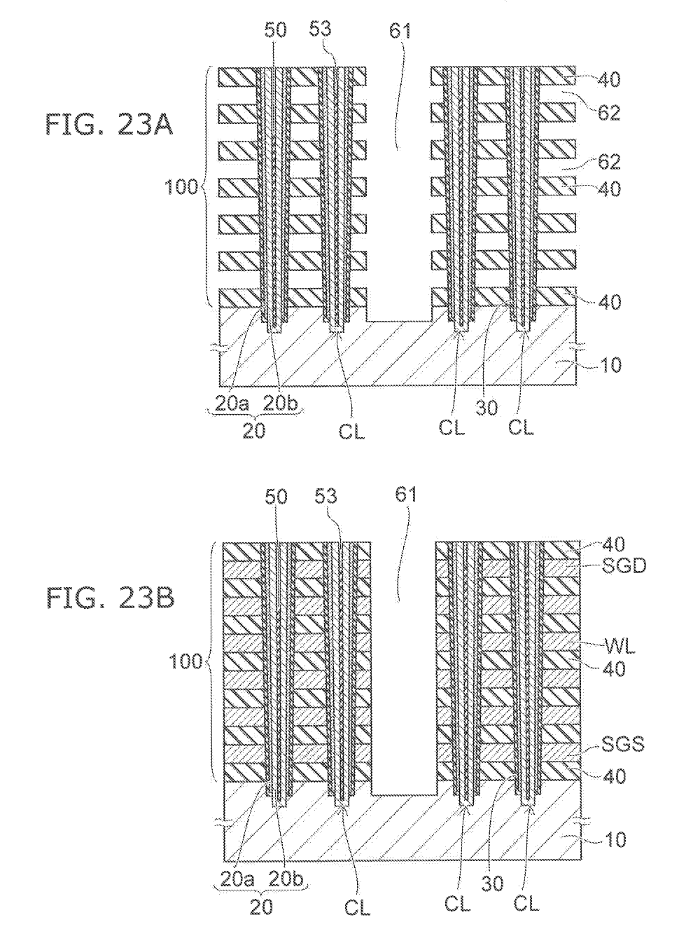

The sacrifice layers 42 are etched away through the slit 61. The removal of the sacrifice layers 42 forms spaces 62 between the insulating layers 40, as shown in FIG. 23A.

The electrode layers WL, the drain-side select gate SGD, and the source-side select gate SGS are formed in the spaces 62 through the slit 61, as shown in FIG. 23B.

The drain-side select gate SGD is formed in the top space 62, the source-side select gate SGS is formed in the bottom space 62, and the electrode layers WL are formed in the spaces 62 between the top space and the bottom space.

Each of the electrode layers WL, the drain-side select gate SGD, and the source-side select gate SGS is a metal layer and contains, for example, tungsten.

The sacrifice layers 42 are replaced with the electrode layers WL, the drain-side select gate SGD, and the source-side select gate SGS also in the stair-shaped portion 309 shown in FIG. 18A.

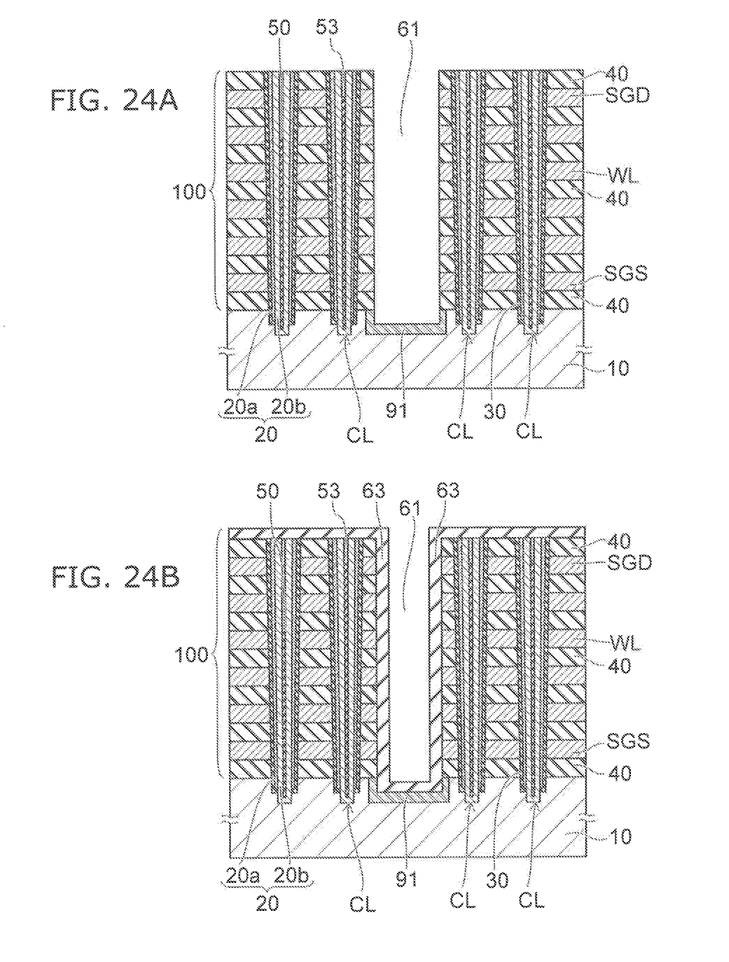

An impurity is then implanted into the surface of the substrate 10 at the bottom of the slit 61, followed by a heat treatment that diffuses the implanted impurity. A contact region 91 shown in FIG. 24A is thus formed on the surface of the substrate 10 at the bottom of the slit 61.

The insulating film 63 is then formed on the inner wall (sidewall and bottom) of the slit 61, as shown in FIG. 24B. The insulating film 63 formed at the bottom of the slit 61 is removed by using the RIE method.

The source layer SL is then buried in the slit 61, as shown in FIG. 25. A lower end portion of the source layer SL is connected to the substrate 10 via the contact region 91. The lower end of each of the channel films 20 and the source layer SL are electrically connected to each other via the substrate 10.

The drain-side select gate SGD is then divided in the Y-direction, as shown in FIG. 1. Further, the bit lines BL shown in FIG. 1, the upper layer interconnect connected to the source layer SL, and other portions are then formed.

The process of forming the stair-shaped portion 301 in the first intermediate film 86 to the process of processing the plurality of first layers (sacrifice layers 42) into a stair-like shape shown in FIG. 6A to FIG. 17B are continuously carried out in the same etching chamber with a desired reduced-pressure atmosphere maintained but not exposed to the atmosphere.

In the stacked body 100, the electrode layers WL may instead be formed without formation of the sacrifice layers 42 as the first layers. In this case, the process of replacing the sacrifice layers 42 with the electrode layers WL is not required.

The layer to be processed is not limited to a stacked body in which different types of films are repeatedly stacked on each other and may be a stacked body having no repeated structure or a monolayer film. The embodiment described above is suitable for formation of a stair-shaped structure having a large number of stairs irrespective of the material and structure of the layer to be processed.

While certain embodiments have been described, these embodiments have been presented by way of example only, and are not intended to limit the scope of the inventions. Indeed, the novel embodiments described herein may be embodied in a variety of other forms; furthermore, various omissions, substitutions and changes in the form of the embodiments described herein may be made without departing from the spirit of the inventions. The accompanying claims and their equivalents are intended to cover such forms or modification as would fall within the scope and spirit of the inventions.

What is claimed is:

1. A method for manufacturing a semiconductor device, comprising;
forming a stacked mask on a layer to be processed, the stacked mask having a plurality of intermediate films and a plurality of mask films alternately stacked;
forming a stair-shaped portion in a top-layer first intermediate film among the plurality of intermediate films, the forming the stair-shaped portion including sliming a top-layer mask film, and etching the first intermediate film exposed by the slimming of the top-layer mask film, the sliming the top-layer mask film and the etching the first intermediate film being repeated multiple times;
forming a first stair-shaped portion in a second intermediate film among the plurality of intermediate films, the second intermediate film being below the first intermediate film, by transferring the stair-shaped portion of an upper intermediate film; and
forming a second stair-shaped portion following the first stair-shaped portion in the second intermediate film, the forming the second stair-shaped portion including slimming a mask film immediately above the second intermediate film, and etching the second intermediate film, the slimming the mask film and the etching the second intermediate film being repeated multiple times.

2. The method according to claim 1, wherein lower-layer-side intermediate films are thicker than upper-layer-side intermediate films, among the plurality of intermediate films.

3. The method according to claim 2, wherein lower intermediate films are thicker.

4. The method according to claim 1, wherein the mask films are slimmed by isotropic dry etching.

5. The method according to claim 1, wherein the forming the stair-shaped portion in the intermediate film includes etching back the intermediate film in a thickness direction by anisotropic dry etching.

6. The method according to claim 1, wherein before a mask film below the top-layer mask film is slimmed, the upper intermediate film immediately above the mask film below the top-layer mask film is removed.

7. The method according to claim 1, wherein a number of stairs of the stair-shaped portion formed in lower intermediate films is greater than a number of stairs of the stair-shaped portion formed in upper intermediate films.

8. The method according to claim 1, further comprising:
forming a foundation mask film made of a material different from a material of the layer to be processed between the layer to be processed and a lowermost intermediate film among the plurality of intermediate films; and
transferring the first stair-shaped portion and the second stair-shaped portion of the lowermost intermediate film to the foundation mask film.

9. The method according to claim 8, wherein the mask films and the foundation mask film are made of a same material.

10. A method for manufacturing a semiconductor device, comprising:
forming a stacked mask on a stacked body having a plurality of first layers and a plurality of second layers alternately stacked, the stacked mask having a first mask film, a plurality of second mask films provided above the first mask film, and a plurality of intermediate films provided between the second mask films and between the first mask film and the second mask films;
forming a stair-shaped portion in a top-layer first intermediate film among the plurality of intermediate films, the forming the stair-shaped portion including slimming a top-layer second mask film, and etching the first intermediate film exposed by the slimming of the top-layer second mask film, the slimming the top-layer second mask film and the etching the first intermediate film being repeated multiple times;
forming a first stair-shaped portion in a second intermediate film among the plurality of intermediate films, the second intermediate film being below the first intermediate film, by transferring the stair-shaped portion of an upper intermediate film;
forming a second stair-shaped portion following the first stair-shaped portion in the second intermediate film, the forming the second stair-shaped portion including slimming a second mask film immediately above the second intermediate film, and etching the second intermediate film, the slimming the second mask film and the etching the second intermediate film being repeated multiple times;
transferring the first stair-shaped portion and the second stair-shaped portion of a lowermost intermediate film among the plurality of intermediate films to the first mask film to form a stair-shaped portion in the first mask film; and
transferring the stair-shaped portion of the first mask film to the stacked body to process the plurality of first layers into a stair-like shape.

11. The method according to claim 10, wherein lower-layer-side intermediate films are thicker than upper-layer-side intermediate films, among the plurality of intermediate films.

12. The method according to claim 11, wherein lower intermediate films are thicker.

13. The method according to claim 10, wherein the second mask films are slimmed by isotropic dry etching.

14. The method according to claim 10, wherein the forming the stair-shaped portion in the intermediate film includes etching back the intermediate film in a thickness direction by anisotropic dry etching.

15. The method according to claim 10, wherein
the forming the first stair-shaped portion in the second intermediate film includes:
etching away part of the stair-shaped portion of the upper intermediate film,
etching away part of the second mask film exposed by the etching away the part of the stair-shaped portion; and
etching part of the second intermediate film exposed by the etching away the part of the second mask film.

16. The method according to claim 15, wherein the part of the second mask film is removed by anisotropic dry etching.

17. The method according to claim 15, wherein an upper second mask film immediately above the upper intermediate film disappears at the time of etching away the part of the second mask film.

18. The method according to claim 10, wherein the forming the stair-shaped portion in the first intermediate film to the processing the first layers into a stair-like shape are performed continuously in a same chamber.

19. The method according to claim 10, further comprising:
forming an interlayer insulating film above a stair-shaped portion of the first layers;
forming contact holes penetrating the interlayer insulating film and reaching each of the first layers; and
forming a conductive film in each of the contact holes.

20. The method according to claim 10, further comprising:
forming a hole in the stacked body, the hole extending in a stacked direction of the first layers and the second layers;
forming a film including a charge storage film on an inner wall of the hole; and
forming a semiconductor film inside the charge storage film in the hole.
